(19) United States
(12) Patent Application Publication
(10) Pub. No.: US 2007/0164633 A1
(43) Pub. Date: Jul. 19, 2007

(54) Quartz SAW sensor based on direct quartz bonding

(75) Inventors: Cornel P. Cobianu, Bucharest (RO); Viorel V. Avramescu, Bucharest (RO); Ion Georgescu, Bucharest (RO)

Correspondence Address: Attorney, Intellectual Property;Honeywell International Inc., 101 Columbia Rd., P.O. Box 2245, Morristown, NJ, 07962, US

(73) Assignee: Honeywell International Inc.

(21) Appl. No.: 11/331,632

(22) Filed: Jan. 13, 2006

(51) Int. Cl. H03H 9/145

(52) U.S. Cl. 310/313 A; 310/313 R

(57) ABSTRACT

A SAW sensor module can be produced with a true all quartz sensor package (TAQSP) attached to a substrate. The TAQSP has a quartz cover direct quartz bonded to a SAW sensor on a quartz substrate. The TAQSP can be mass produced by direct quartz bonding a quartz cover wafer, having many covers, to a quartz sensor wafer, having many sensors, thereby producing a wafer tandem. The wafer tandem can be further processed because the bond protects the sensors within. Individual sensor packages can be obtained by cutting stripes out of the cover wafer, revealing SAW sensor bonding pads, and then dicing the wafer tandem. A SAW sensor module results when the sensor packages are attached to an antenna bearing substrate and then sealed.

### TECHNICAL FIELD

Embodiments relate to the field of surface acoustic wave sensors. Embodiments also relate to processing quartz wafers and sensor packaging.

### BACKGROUND

Surface acoustic wave (SAW) devices are commonly used to filter signals in electronic devices and are also used as sensors due to acoustic wave sensitivity to the physico-chemical measurands such as pressure and temperature. It is well known to those skilled in the art of surface acoustic wave devices that these SAW sensors can be either SAW delay lines or SAW resonators fabricated to be responsive to different non-electric measurands. The main component of a SAW device is a comb metal structure called the interdigital transducer (IDT), which is used to generate surface acoustic waves from an applied electric signal and vice-versa by the piezoelectric effect developed in the piezoelectric crystals/polycrystals on which the IDT is deposited. Actually, a simple example of a SAW delay line device could be obtained from two IDT structures separated by a certain distance on the same substrate. FIG. 18, labeled as “prior art” illustrates a SAW delay line device 1810, where two comb structures are separated by a distance “d” and patterned onto a piezoelectric substrate 1801. An electrical input signal is passed to the SAW delay line through the input IDT 1811 having a first input pad 1802 and a second input pad 1805. The first input pad is electrically connected to the first comb electrode 1803. The second input pad is connected to the second comb electrode 1804. The input IDT 1811 converts the electrical input signal into an acoustic signal that propagates along the surface of the piezoelectric substrate 1801 to the output IDT 1812 that is also patterned onto the same piezoelectric substrate 1801. The output IDT 1812 converts the acoustic signal into an electrical output signal that can be obtained from the first output pad 1806 and the second output pad 1807. The SAW sensor is obtained when the propagation velocity of the acoustic wave is changed in the presence of a physical measurand from outside. If the output IDT 1812 is replaced by a single or a series of reflectors, a reflective SAW delay is obtained, which can be used as a wireless SAW sensor when the first input pad 1802 and second input pad 1805 are connected to an antenna. For simplicity reasons, the SAW sensor shall herein be represented by an IDT pattern.

Stress and strain on the piezoelectric substrate cause the acoustic signal to change. The changes can be detected in the electrical output signal. Stress and strain produce a smaller measurable effect on an acoustic signal propagating along a thick substrate than along a thin substrate. Thinning an area of the substrate under the SAW sensor enhances the measurable effect. The thinned area is called a diaphragm. The act of thinning the substrate under the SAW sensor is called releasing the diaphragm.

A cover is often attached to one side of a SAW sensor. The cover can protect sensor. The cover can also produce a reference chamber if it isolates a sealed volume when it is attached to the SAW sensor. Reference chambers are often used in SAW pressure sensors. Attaching a cover to a SAW sensor, however, can introduce stress and strain in the sensor. The cover induced strain can cause poor sensor measurements. The process of bonding the sensor and cover together can introduce strain. Furthermore, if the cover material is different from the sensor substrate material then environmental effects such as temperature changes can cause unintended and inconsistent strain on the SAW sensor.

Ideally, a quartz cover can be bonded to a quartz sensor substrate to minimize unintentional environmental effects. Direct quartz bonding techniques can produce a chemical bond that attaches one quartz surface directly to another quartz surface. In one technique, silanol groups (Si—OH) are produced on both quartz surfaces, the surfaces are pressed together and the assembly is heated to around 450° C. During the heating treatment, silanol groups on the SAW quartz wafer will react with silanol groups on the quartz cover wafer forming covalent bonds Si—O—Si between the two wafers with oxygen atoms covalently bonded to both wafers acting as a bridge and making a strong wafer bonding. A water molecule will be released for each formation of Si—O—Si covalent bond. In another technique, a plasma treatment creates reactive dangling bonds on each surface and then the surfaces are pressed together. Those skilled in the art of quartz processing know of these and other techniques, particularly direct quartz bonding techniques, for bonding quartz surface.

Other circuit elements in addition to a SAW sensor are required for producing measurements. Typically, those other circuit elements include a printed circuit board (PCB) and one or more antennas. The antennas are often patterned directly onto the PCB as traces. The SAW sensor, and any other necessary circuit elements, is attached to the PCB using any of a variety of techniques known to those skilled in the art of electronics manufacture. A SAW sensor module is a populated PCB having a SAW sensor. SAW sensor modules must often be sealed, such as with gel, epoxy, or another material in order to keep unwanted material from the SAW sensor. Those skilled in the art of SAW sensor modules know of many sealing materials and techniques applicable to SAW sensors.

Current technology does not, however, supply systems or methods for the batch processing of covered and sealed all quartz SAW sensors because individual quartz covers are attached to individual quartz SAW sensors. Aspects of the embodiments directly address the shortcoming of current technology by the direct quartz bonding of processed quartz substrates before dicing.

### BRIEF SUMMARY

The following summary is provided to facilitate an understanding of some of the innovative features unique to the embodiments and is not intended to be a full description. A full appreciation of the various aspects of the embodiments can be gained by taking the entire specification, claims, drawings, and abstract as a whole.

It is therefore an aspect of the embodiments to process a quartz cover wafer to produce a sensor recess pattern and a stripe recessed pattern. The sensor recess pattern is an array of sensor recesses. The stripe recessed pattern is a series of parallel recessed zones called stripes. The two patterns are aligned to one another and with the stripes perpendicular to the rows of sensor recesses.

It is another aspect of the embodiments to process a SAW quartz wafer to produce a SAW sensor pattern. The SAW sensor pattern is an array of SAW sensors. The SAW sensor pattern is arranged to align with the sensor recess pattern on the quartz cover wafer.

It is yet another aspect of the embodiments to align the quartz cover wafer and the SAW quartz wafer and then to direct quartz bond them. The quartz surfaces of the two wafers are coincident, meaning touching, except in those places where the SAW sensors align with the sensor recesses and where the stripes traverse the cover. The coincident surfaces are direct quartz bonded. Any of the known direct quartz bonding techniques is sufficient, including the methods discussed above involving plasma treatment for quartz surface activation or hydrophilization treatment for silanol (Si—OH) group formation. The SAW sensor pattern is now sealed within the sensor recess pattern and stripe recess patterns. The two quartz wafers, being direct quartz bonded together, form a wafer tandem.

It is a further aspect of the embodiments to release the quartz diaphragm of each SAW sensor. This operation can be done to the entire SAW sensor array at once without damaging the SAW sensors because only one side of the SAW quartz wafer can be etched. The other side, containing the SAW devices, is bonded to, sealed against, and protected by the quartz cover wafer. A metal masking layer can protect the entire surface of cover wafer during diaphragm release and also a metal masking layer can be used on the back side of the quartz SAW wafer for the selective etching of the SAW wafer in order to make quartz diaphragm. The continuous direct quartz bonding at the periphery of the wafer tandem will protect it against penetration of etching solution to the SAW surface.

It is a yet further aspect of the embodiments to separate individual covered SAW sensors from the wafer tandem. The stripes are cut away, perhaps by sawing or cutting along the edges of each stripe. During processing, such as during the diaphragm release step, the outer surfaces of the wafer tandem can lose transparency. Without transparency, the stripes cannot be seen. Alignment marks can be placed on the quartz cover wafer or on the SAW quartz wafer such that the stripes can be located without being seen. The wafer tandem with stripes removed can be diced using standard wafer dicing techniques.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a sensor recess pattern of the cover wafer in accordance with aspects of the embodiments;

FIG. 2 illustrates a stripe recess pattern of the cover wafer in accordance with aspects of the embodiments;

FIG. 3 illustrates a quartz cover wafer processed to produce a sensor cover pattern and a stripe recess pattern in accordance with aspects of the embodiments;

FIG. 4 illustrates an expanded view of sensor recess and stripes on a quartz wafer in accordance with aspects of the embodiments;

FIG. 5 illustrates a first side view along a first cut line of the expanded view of FIG. 4 in accordance with aspects of the embodiments;

FIG. 6 illustrates a second side view along a second cut line of the expanded view of FIG. 4 in accordance with aspects of the embodiments;

FIG. 7 illustrates a third side view along a third cut line of the expanded view of FIG. 4 in accordance with aspects of the embodiments;

FIG. 8 illustrates a SAW sensor array produced on a SAW quartz wafer in accordance with aspects of the embodiments;

FIG. 9 illustrates an expanded view of SAW sensors aligned with sensor recesses in a wafer tandem in accordance with aspects of the embodiments;

FIG. 10 illustrates a wafer tandem in accordance with aspects of the embodiments;

FIG. 11 illustrates a side view of a wafer tandem in accordance with aspects of the embodiments;

FIG. 12 illustrates a first side view along a first cut line 901 of the expanded view of FIG. 9 in accordance with aspects of the embodiments;

FIG. 13 illustrates a second side view along a second cut line 902 of the expanded view of FIG. 9 in accordance with aspects of the embodiments;

FIG. 14 illustrates a third side view along a third cut line 903 of the expanded view of FIG. 9 in accordance with aspects of the embodiments;

FIG. 15 illustrates an a covered SAW sensor in accordance with aspects of the embodiments;

FIG. 16 illustrates a covered SAW sensor module in accordance with aspects of certain embodiments;

FIG. 17 illustrates a high level flow diagram of producing a SAW sensor module having an all quartz covered SAW sensor in accordance with aspects of certain embodiments; and

FIG. 18, labeled as “prior art” illustrates a SAW sensor patterned on a substrate.

### DETAILED DESCRIPTION

The particular values and configurations discussed in these non-limiting examples can be varied and are cited merely to illustrate at least one embodiment and are not intended to limit the scope thereof. In general, the figures are not to scale.

FIG. 1 illustrates a sensor recess pattern 101 in accordance with aspects of the embodiments. The sensor recess pattern 101 is an array of sensor recesses that each has a sensor body recess 102 and a sensor lead recess 103. The sensor lead recess 103 is shown as being continuous with the adjacent sensor body recess.

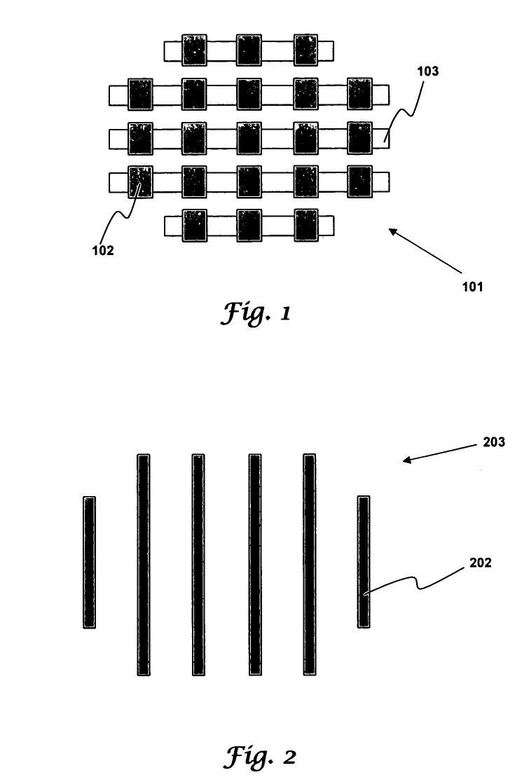

FIG. 2 illustrates a stripe recessed pattern 203 in accordance with aspects of the embodiments. The stripe recessed pattern is a series of recessed zones 202 in the quartz cover wafer.

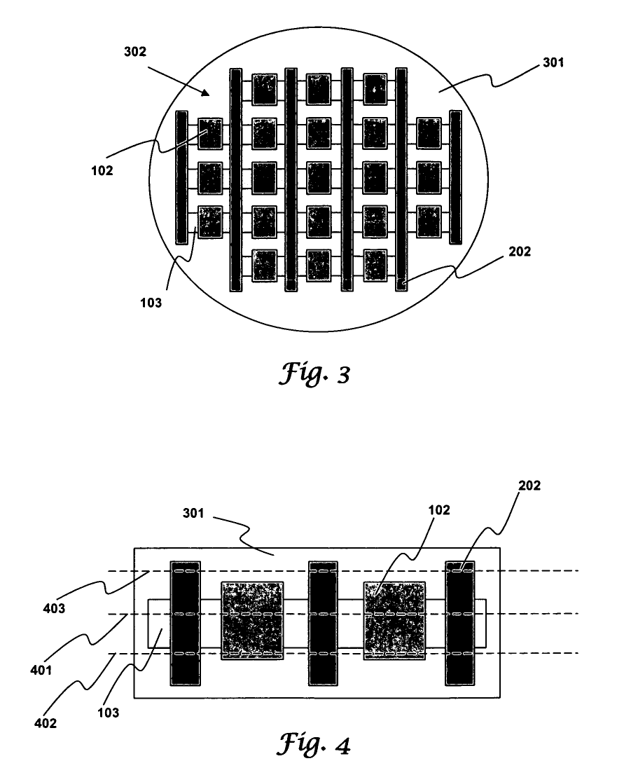

FIG. 3 illustrates a quartz cover wafer 301 processed to produce a sensor cover pattern 302 in accordance with aspects of the embodiments. As can be seen in the figure, the sensor cover pattern 302 includes the sensor recess pattern of FIG. 1 and the stripe recessed pattern of FIG. 2. Each stripe 202 is aligned perpendicular to the sensor lead recesses 103 and between the sensor body recesses 102.

FIG. 4 illustrates an expanded view of sensor recesses and stripes 202 on a quartz cover wafer 301, in accordance with aspects of the embodiments. Three cut lines are also shown. The first cut line 401 goes across the sensor lead recesses 103, stripe recesses 202, and sensor body recesses 102. The second cut line 402 goes across the stripe recesses 202, and sensor body recesses 102. The third cut line 403 goes across the stripe recesses 202.

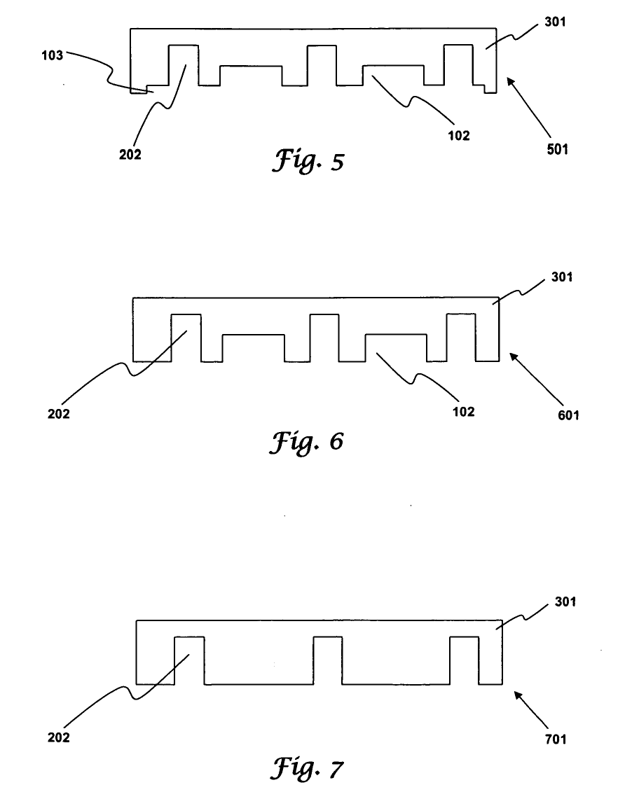

FIG. 5 illustrates a first side view along the first cut line 401 of the expanded view of FIG. 4 in accordance with aspects of the embodiments. This cut view is called the first cover wafer cut view 501. Sensor lead recesses 103, sensor body recesses 102, and stripe recesses 202 can be seen in the quartz cover wafer 301.

FIG. 6 illustrates a second side view along the second cut line 402 of the expanded view of FIG. 4 in accordance with aspects of the embodiments. This cut view is called the second cover wafer cut view 601. Sensor body recesses 102, and stripe recesses 202 can be seen in the quartz cover wafer 301.

FIG. 7 illustrates a third side view along the third cut line 403 of the expanded view of FIG. 4 in accordance with aspects of the embodiments. This cut view is called the third cover wafer cut view 701. Stripe recesses 202 can be seen in the quartz cover wafer 301.

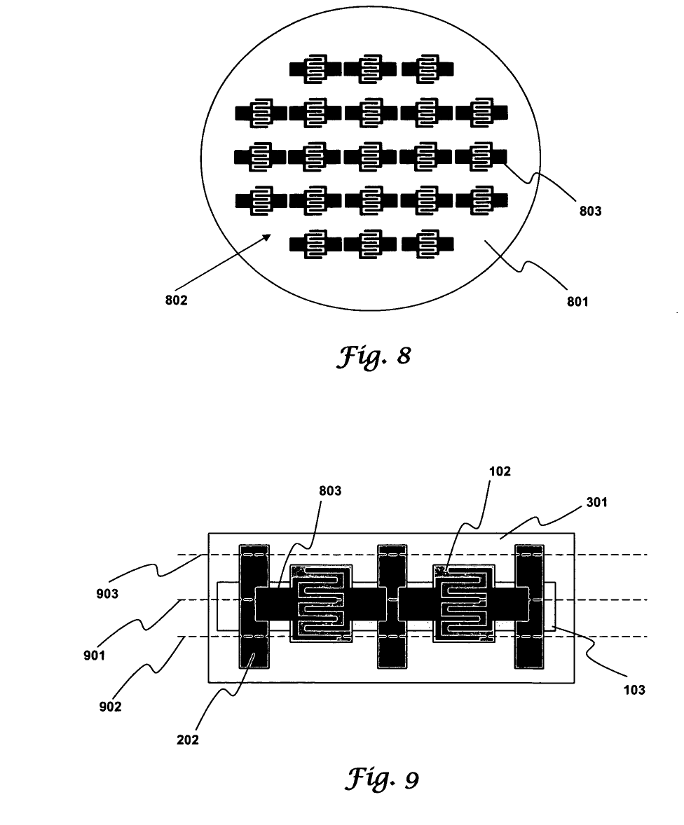

FIG. 8 illustrates a SAW sensor array 802 produced on a SAW quartz wafer 801 in accordance with aspects of the embodiments. The SAW sensor array is made of many SAW sensors 803.

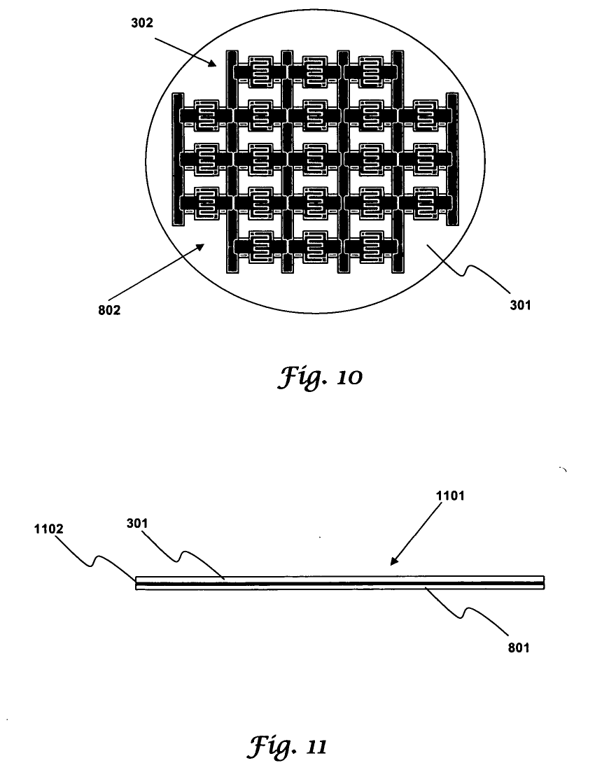

FIG. 9 illustrates an expanded view of SAW sensors 803 aligned with sensor and stripe recesses in a wafer tandem in accordance with aspects of the embodiments. The quartz cover wafer 301 lies on top of the SAW quartz wafer, which cannot be seen. The stripes recesses 202, sensor lead recesses 103, and sensor body recesses 102 formed into the quartz cover wafer 301 can be seen. The SAW sensors 803 formed on the SAW quartz wafer can be seen aligned with and laying within the sensor body recesses 102 and sensor lead recesses 103. FIG. 9 also has three cut lines. The first cut line 901 is analogous the FIG. 4 first cut line 401. The second cut line 902 is analogous the FIG. 4 second cut line 402. The third cut line 903 is analogous the FIG. 4 third cut line 403. FIG. 10 illustrates a full view of the wafer tandem in accordance with aspects of the embodiments. The sensor cover pattern 302 can be seen aligned with the sensor pattern 802. Here, the SAW quartz wafer is under the quartz cover wafer 301.

FIG. 11 illustrates a first side view of a wafer tandem 1101 in accordance with aspects of the embodiments. The quartz cover wafer 301 lies on top of the SAW quartz wafer 801. A seam 1102 is shown between the two wafers for illustrative purposes only. In actual practice, there is no seam because direct quartz bonding is seamless. It is possible that, from the side as shown, the devices and topography between the wafers could be seen.

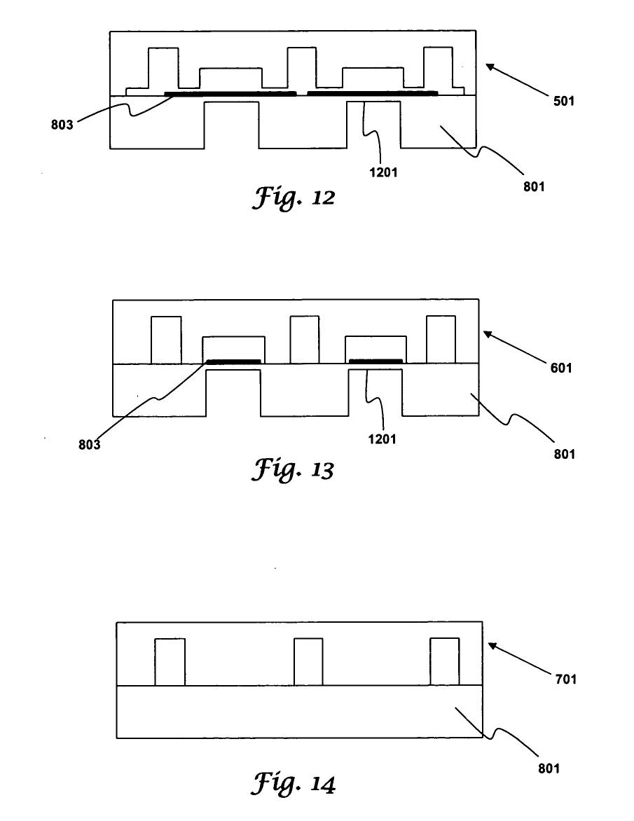

FIG. 12 illustrates a second side view along the first cut line 901 of the expanded view of FIG. 9 in accordance with aspects of the embodiments. The first cover wafer cut view 501 is seen overlying a portion of the SAW quartz wafer 801. The SAW sensor 803 can be seen aligned with the sensor recesses and on top of the SAW quartz wafer 801. The quartz diaphragm 1201 can also be seen because it has been released. At the edges of the wafer tandem there is always a continuous direct quartz bonding zone to protect the SAW wafer surface against etching liquid penetration during diaphragm release by wet etching.

FIG. 13 illustrates a third side view along the second cut line 902 of the expanded view of FIG. 9 in accordance with aspects of the embodiments. The second cover wafer cut view 601 is seen overlying a portion of the SAW quartz wafer 801. At the edges of the wafer tandem there is always a continuous direct quartz bonding zone to protect the SAW wafer surface during diaphragm release by wet etching. The SAW sensor 803 can be seen aligned with the sensor recesses and on top of the SAW quartz wafer 801. The quartz diaphragm 1201 can also be seen because it has been released. A portion of the SAW sensor 803 is obscured because the sensor lead recess is not present in this view.

FIG. 14 illustrates a side view along the third cut line 903 of the expanded view of FIG. 9 in accordance with aspects of the embodiments. The third cover wafer cut view 701 is seen overlying a portion of the SAW quartz wafer 801. The SAW sensor, quartz diaphragm, sensor lead recess, and sensor body recess are not present in this view. The recessed stripes are present in this view. Examining FIGS. 12 and 13 reveals that cutting away the stripes will reveal the SAW sensor leads.

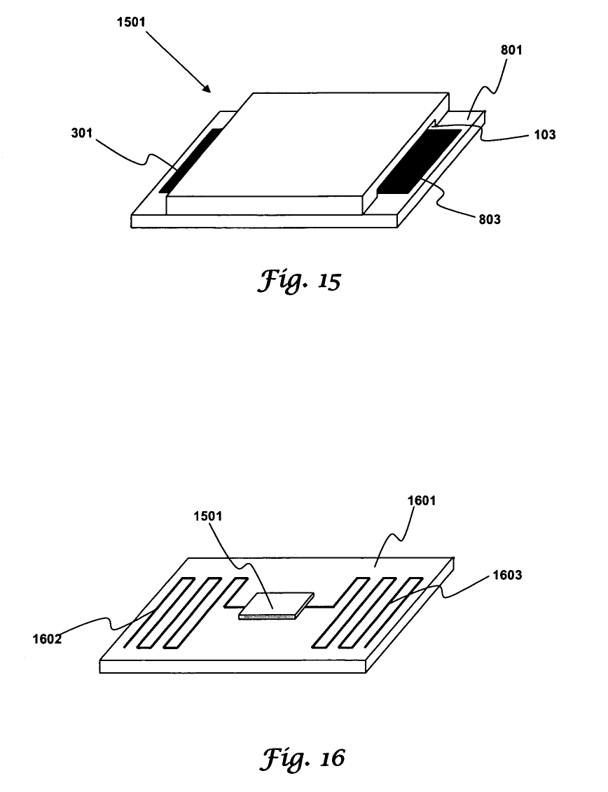

FIG. 15 illustrates a covered SAW sensor 1501 in accordance with aspects of the embodiments. A covered quartz sensor 1501 can be obtained by removing the stripes to reveal the leads of the SAW sensors 803 underneath. Next, the wafer tandem is diced in the same manner as any wafer is diced. Dicing is a common operation in wafer processing in which a processed wafer is cut into individual components. Here, dicing along the strip direction cuts through only the quartz cover wafer 301 while dicing in the perpendicular direction cuts through SAW quartz wafer 801 and the quartz cover wafer 301. A sensor lead recessed zone 103 can be seen on the right side of covered SAW sensor 1501 after dicing. The gap between sensor lead and quartz cover can be sealed in subsequent steps aimed toward pressure reference chamber formation.

It is important to note here that contaminants can get into the covered SAW sensor because the remaining part of the sensor lead recess 103, directly above the lead portion of the SAW sensor 803 and below the quartz cover, is not sealed. Sealing the sensor lead recess protects the SAW sensor and can create a sealed reference chamber. Those practiced in the arts of sensor production or electronics manufacture know of many techniques for sealing an electronic component such as the covered SAW sensor.

FIG. 16 illustrates a covered SAW sensor module in accordance with aspects of certain embodiments. The covered SAW sensor 1501 is flipped over so that the SAW quartz substrate, formally part of the SAW quartz wafer, is on top. As such, the SAW sensor leads can be bonded to the circuit substrate 1601. One SAW sensor lead is electrically connected to a first antenna 1603 while the other is electrically connected to a second antenna 1602. The circuit substrate can be any material used for producing printed circuit elements. A printed circuit board (PCB) is one example of a circuit substrate.

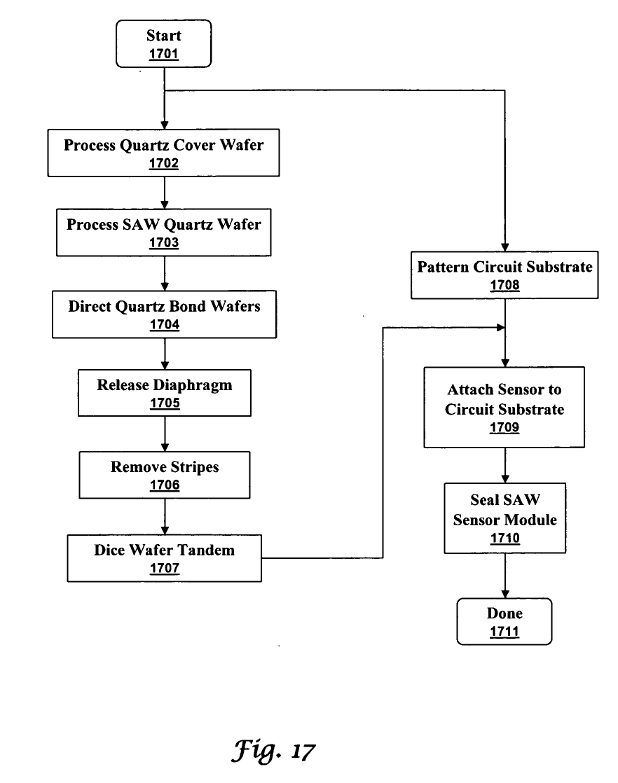

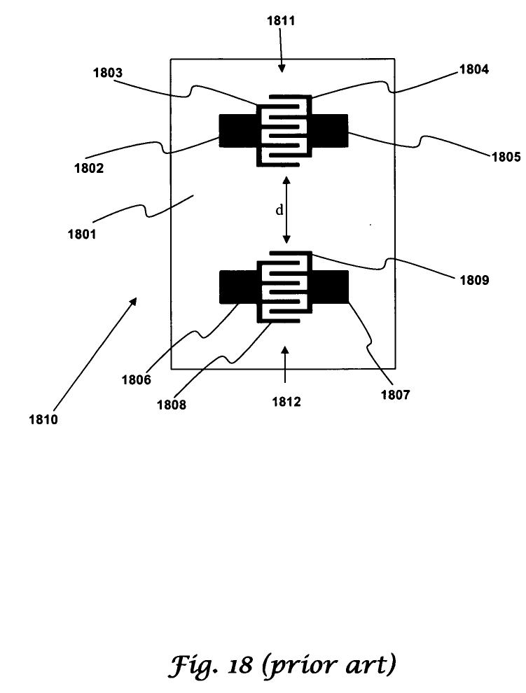

FIG. 17 illustrates a high level flow diagram of producing a SAW sensor module having an all quartz covered SAW sensor in accordance with aspects of certain embodiments. After the start 1701, the quartz cover wafer is processed 1702 to produce a sensor cover pattern. As discussed above, a sensor cover pattern has properly aligned stripes recesses and sensor recesses. Next the SAW quartz wafer is processed 1703 to produce an array of SAW sensors. Next, the wafers are direct quartz bonded 1704 to produce a wafer tandem. The diaphragm is released 1705 with the quartz cover wafer protecting the SAW sensors. Finally, the stripes are removed 1706 and the wafer tandem is diced 1707 to produce many individual covered SAW sensors.

Also after the start 1701, the circuit substrate is patterned 1708. A printed circuit board is an example of a patterned circuit substrate. The circuit substrate can be processed in other ways as well before the covered SAW sensor is ready for attachment. Regardless, once the circuit substrate is prepared and the covered SAW sensor is ready, the covered SAW sensor is attached to the circuit substrate 1709 to produce a SAW sensor module. The SAW sensor module can be sealed 1710 before the process is done 1711. Sealing the covered SAW sensor is discussed above. The same, or a similar, result can be obtained by sealing the SAW sensor module before attaching it to the circuit substrate 1709.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

1. A method comprising:
processing a quartz cover wafer to produce a sensor recess pattern and a stripe recess pattern wherein the sensor recess pattern comprises a multitude of sensor recesses, wherein the stripe recess pattern comprises a multitude of stripes, and wherein the stripe recess pattern is perpendicular and aligned with the sensor cavity pattern;
processing a SAW quartz wafer to produce a SAW sensor pattern comprising a multitude of SAW sensors;
aligning the quartz cover wafer and the SAW quartz wafer such that the multitude of SAW sensors align with multitude of sensor recesses;
direct quartz bonding the quartz cover wafer and the SAW quartz wafer such that all coincident quartz surfaces bond together and wherein the multitude of SAW sensors are sealed within the multitude of sensor recesses thereby producing a wafer tandem;
releasing quartz diaphragms by deep etching the SAW quartz wafer wherein only one side of the SAW quartz wafer can be etched because the other side is bonded to the quartz cover wafer, having a continuous bonded zone at the periphery of the tandem and having a metal layer mask deposited on all regions of wafer tandem that need protection during deep quartz etching;
removing the multitude of stripes out of the quartz cover wafer; and
dicing the wafer tandem to produce a multitude of covered SAW sensors.

2. The method of claim 1 wherein the multitude of stripes are removed from the quartz cover wafer by cutting along the edges of the stripes.

3. The method of claim 2 further comprising producing at least one alignment mark on the quartz cover wafer such that the edges of the stripes can be located.

4. The method of claim 3 wherein direct quartz bonding is performed by a series of steps comprising plasma treating the quartz surfaces that are to be bonded and pressing the plasma treated surfaces together.

5. The method of claim 3 wherein direct quartz bonding is performed by a series of steps comprising forming silanol groups on the surfaces to be bonded, pressing the surfaces to be bonded together, and then heating.

6. The method of claim 1 further comprising producing at least one alignment mark on the quartz cover wafer such that the edges of the stripes can be located.

7. The method of claim 1 wherein direct quartz bonding is performed by a series of steps comprising plasma treating the quartz surfaces that are to be bonded and pressing the plasma treated surfaces together.

8. The method of claim 1 wherein direct quartz bonding is performed by a series of steps comprising forming silanol groups on the surfaces to be bonded, pressing the surfaces to be bonded together, and then heating.

9. A method comprising:
processing a quartz cover wafer to produce a sensor recess pattern and a stripe recess pattern wherein the sensor overlay pattern comprises a multitude of sensor recesses, wherein the stripe recess pattern comprises a multitude of stripes, and wherein the stripe recess pattern is perpendicular and aligned with the sensor cavity pattern;
processing a SAW quartz wafer to produce a SAW sensor pattern comprising a multitude of SAW sensors;
aligning the quartz cover wafer and the SAW quartz wafer such that the multitude of SAW sensors align with the multitude of sensor recesses;
direct quartz bonding the quartz cover wafer and the SAW quartz wafer such that all coincident quartz surfaces bond together and wherein the multitude of SAW sensors are sealed within the multitude of sensor recesses thereby producing a wafer tandem;
releasing the quartz diaphragm by deep etching the SAW quartz wafer wherein only one side of the SAW quartz wafer can be etched because the other side is bonded to the quartz cover wafer, wherein the periphery of the wafer tandem is continuously bonded on the whole edge, and wherein the outer surface of the quartz cover wafer and the surviving backside of the SAW quartz wafer are protected with metal masking layers;
sawing the multitude of stripes out of the quartz cover wafer;
dicing the wafer tandem to produce a multitude of covered SAW sensors,
patterning a substrate to produce at least one antenna electrically connected to at least one bonding pad;
attaching one of the multitude of covered SAW sensors to the substrate wherein the SAW sensor is bonded to at least one of the at least one bonding pad to produce a SAW sensor module;
sealing the SAW sensor module;

10. The method of claim 9 further comprising gel filling the SAW sensor module.

11. The method of claim 10 further comprising producing at least one alignment mark on the quartz cover wafer such that the stripes can be located.

12. The method of claim 11 wherein direct quartz bonding is performed by a series of steps comprising plasma treating the quartz surfaces that are to be bonded and pressing the plasma treated surfaces together.

13. The method of claim 11 wherein direct quartz bonding is performed by a series of steps comprising forming silanol groups on the surfaces to be bonded, pressing the surfaces to be bonded together, and then heating.

14. The method of claim 9 further comprising producing at least one alignment mark on the quartz cover wafer such that the multitude of stripe recesses can be located.

15. The method of claim 9 wherein direct quartz bonding is performed by a series of steps comprising plasma treating the quartz surfaces that are to be bonded and pressing the plasma treated surfaces together.

16. The method of claim 9 wherein direct quartz bonding is performed by a series of steps comprising forming silanol groups on the surfaces to be bonded, pressing the surfaces to be bonded together, and then heating.

17. A system comprising:
a quartz cover wafer comprising a sensor recess pattern and a stripe recess pattern wherein the sensor recess pattern comprises a multitude of sensor recesses, wherein the stripe recess pattern comprises a multitude of stripes, and wherein the stripe recess pattern is perpendicular and aligned with the sensor cavity pattern;
a SAW quartz wafer comprising a SAW sensor pattern comprising a multitude of SAW sensors; and
a direct quartz bond wherein the quartz cover wafer and the SAW quartz wafer are direct quartz bonded wherein the multitude of SAW sensors align with the multitude of sensor recesses, wherein all coincident quartz surfaces bond together, and wherein the multitude of SAW sensors are sealed within the multitude of sensor recesses thereby providing a wafer tandem.

18. The system of claim 1 further comprising at least one alignment mark on the quartz cover wafer such that the stripes can be located inside the wafer tandem.

19. The system of claim 18 wherein the direct quartz bond is formed by producing reactive dangling bonds on the quartz surfaces that are to be bonded and pressing together the surfaces that are to be bonded.

20. The system of claim 18 wherein the direct quartz bond is formed by producing silanol groups on the surfaces to be bonded, pressing the surfaces to be bonded together, and then heating in order to obtain Si—O—Si covalent bonds responsible for direct bonding.
